(19) United States
(12) Patent Application Publication
(10) Pub. No.: US 2026/0202471 A1
(43) Pub. Date: Jul. 16, 2026

(54) TESTING INTEGRATED CIRCUITS VIA SCAN CHAIN COMPRESSION

(71) Applicant: International Business Machines Corporation, Armonk, NY (US)

(72) Inventor: Nilabha Dev, Kolkata (IN)

(73) Assignee: International Business Machines Corporation, Armonk, NY (US)

(21) Appl. No.: 19/019,771

(22) Filed: Jan. 14, 2025

(51) Int. Cl. G01R 31/3185

(52) U.S. Cl. CPC G01R 31/318536

(57) ABSTRACT

A method for performing integrated circuit testing is presented. A compactor is generated using explicit expander graph construction. A decompressor and the generated compactor are inserted within a device-under-tested (DUT). After feeding a compressed test pattern into the DUT, the compressed test pattern is expanded via the decompressor into internal scan-ins within the DUT. Subsequently, the internal scan-out data is compressed into compressed output vectors using the generated compactor. After shifting out from the DUT, the compressed output vectors are compared to a set of desired outputs in order to determine a pass/fail status of the DUT.

### TECHNICAL FIELD

The present invention relates to chip testing in general, and in particular, to integrated circuit testing via scan chain compression.

### BACKGROUND

A scan chain is commonly employed for testing integrated circuits (ICs). A scan chain is a sequence of flip-flops connected in series to form a shift register. By using a scan chain, a set of test patterns is allowed to be ingested into a chip, and the internal states of the chip can be observed by shifting out results from the chip. As chips become more complex, the number of flip-flops also increases, which makes testing slower and more expensive because more test patterns are required and more bits are needed to be shifted in and out from chips.

The efficiency of IC testing can be improved by using scan chain compression. Scan chain compression compresses the test data that are needed to be loaded into a chip (test stimuli compression) and compresses the chip's output responses to minimize data to be shifted out (response compaction). With scan chain compression, the volume of test data and the time required for IC testing can be reduced without compromising fault coverage.

There are two key components to scan chain compression, namely, a decompressor and a compactor (or compressor), both are typically located within a chip to be tested. The decompressor expands compressed input test patterns into internal scan-ins within the chip to be tested. The compactor compresses internal scan-outs data into output channels by combining multiple test responses into fewer bits (known as compressed output vectors) to be shifted out from the chip to be tested. The compressed output vectors are subsequently compared to the desired outputs in the memory of automated testing equipment (ATE) to determine a pass/fail status of the chip.

Scan chain compression works quite well except that conventional compactors are susceptible to unknowns (i.e., Xs) in a circuit. For example, an X in a scan chain can corrupt a whole signature in a multiple-input signature register based compactor. An X can also cause masking of multiple internal scan chains in an XOR compressor. So, the presence of Xs can cause substantial test coverage loss.

There are techniques designed to overcome the X source problems in compactors. X-blocking techniques, such as masking, are often utilized to control Xs from corrupting the compactors. For example, linear space compactors can be generated to tolerate a certain amount of Xs in the outputs. This technique, known as X-tolerance, is a design-for-test technique to provide immunity to compactors from Xs in a device-under-test. However, each of the above-mentioned X-blocking techniques has its drawbacks.

Consequently, it would be desirable to provide an improved compactor to be utilized in scan chain compression for testing IC chips.

### SUMMARY OF THE INVENTION

In accordance with one embodiment of the present invention, a compactor is generated using explicit expander graph construction. A decompressor and the generated compactor are inserted within a device-under-tested (DUT). After feeding a compressed test pattern into the DUT, the compressed test pattern is expanded via the decompressor into internal scan-ins within the DUT. Subsequently, the internal scan-out data is compressed into compressed output vectors using the generated compactor. After shifting out from the DUT, the compressed output vectors are compared to a set of desired outputs in order to determine a pass/fail status of the DUT.

### BRIEF DESCRIPTION OF THE DRAWINGS

FIG. 1 is a block diagram of a chip testing system in which one embodiment of the present invention can be incorporated;

FIG. 2A is a flowchart of an algorithm for using expander graph to generate a compactor to be utilized in scan chain compression for testing integrated circuit chips, according to one embodiment of the present invention;

FIG. 2B is the pseudo code for the algorithm from FIG. 2A, according to one embodiment of the present invention;

FIG. 2C illustrates an explicit expander graph edge generator that uses the pseudo code from FIG. 2B;

FIG. 3 is an example adjacency matrix of a compactor having 9 scan channels and 5 scan outs;

FIG. 4 is a flowchart of a refinement algorithm, according to one embodiment of the present invention; and

FIG. 5 is a block diagram of a computing environment in which an embodiment of present invention can be executed.

In accordance with common practice, various features illustrated in the drawings may not be drawn to scale. Accordingly, dimensions of the various features may be arbitrarily expanded or reduced for clarity. In addition, some of the drawings may not depict all of the components of a given system, method, or device. Finally, like reference numerals may be used to denote like or corresponding features in the specification and figures.

### DETAILED DESCRIPTION OF ILLUSTRATIVE EMBODIMENT

According to an aspect of the invention, a technique of testing integrated circuits includes generating a compactor by using explicit expander graphs and inserting the generated compactor and a decompressor within a device-under-test (DUT). A compressed test pattern is fed into the DUT and expanded via the decompressor into internal scan-ins within the DUT. Internal scan-outs data are compressed to obtain compressed output vectors via the generated compactor. The compressed output vectors are shifted out from the DUT and compared to a set of desired outputs in order to determine a pass/fail status of said DUT.

Generating a compactor using expander graphs is a new approach to solving the scan compression problem. The generated compactor meets X-tolerance criteria specified in the literature. It also has balanced fan-in for the scan-outs and provides good compression with higher X-tolerance with limited scan outs.

In some embodiments, generating a compactor includes combining a set of internal scan channels and a set of external scan outs to generate a set of mapped pair of candidate edges. This technique of generating a compactor is separable from generating a compactor generally and is one way of generating a set of mapped pair of candidate edges of expander graphs.

In some embodiments, generating a compactor further includes representing the compactor as a bipartite graph between a set of internal scan channels m to a set of external scan-out pins n in the expander graph. This technique of generating a compactor is separable from generating a compactor generally and is an alternative way of generating a set of mapped pair of candidate edges of expander graphs.

In some embodiments, generating a compactor further includes verifying that no two rows in a hash table have the same binary representation. This technique of generating a compactor is separable from generating a compactor generally and serves to minimize the unknown X.

In some embodiments, the verification of the hash table further includes a step of verifying that the generated compactor meets expander graph criteria. This technique of generating a compactor is separable from generating a compactor generally and ensures that the generated compactor meets expander graph criteria.

### Chip Testing System

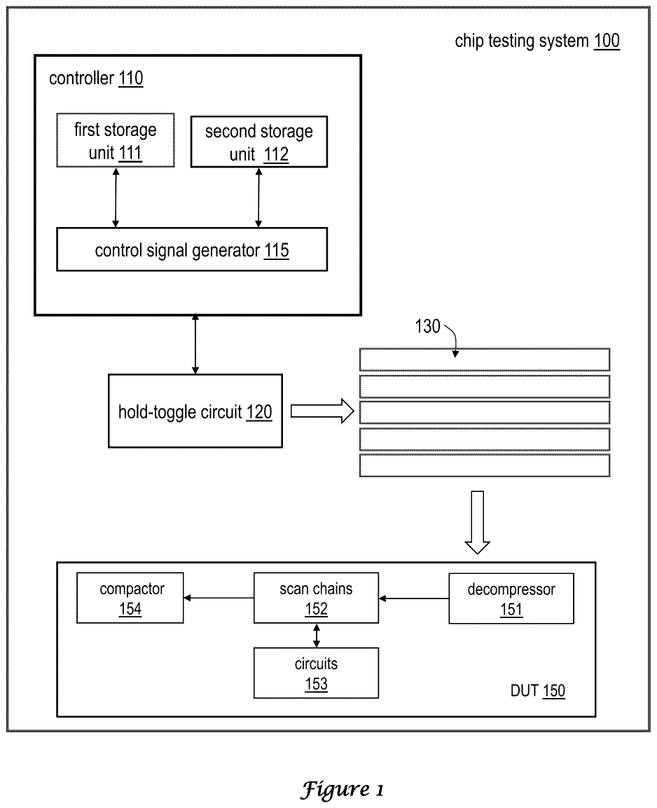

Referring now to the drawings, and in particular to FIG. 1, there is illustrated a block diagram of a chip testing system in which one embodiment of the present invention can be incorporated. As shown, a chip testing system 100 includes a controller 110 and a hold-toggle circuit 120. Controller 110 includes a first storage unit 111, a second storage unit 112, and a control signal generator 115. First storage unit 111 stores operational mode information. The operational mode information determines which mode (a full-toggle mode or a hold-toggle mode) a scan chain operates when a test pattern 130 is being shifted into scan chains 152 within a device-under-test (DUT) 150. Scan chains 152, which include scan cells, are configured in a test mode to shift in test pattern 130, apply test patterns 130 to circuits 153, capture test responses of circuits 153, and shift out the test responses.

Scan chains 152 operating in the full-toggle mode receives bits based on corresponding bits of test pattern 130. Scan chains 152 operating in the hold-toggle mode receives bits based on corresponding bits of test pattern 130 (toggling) only in a predetermined number of inconsecutive shift clock cycles and constant bits (holding) in the rest of shift clock cycles for shifting test pattern 130 into scan chains 152. The operational mode information may be delivered to first storage unit 111 from an on-chip or off-chip storage location, or by a processor or automated test equipment (ATE).

Second storage unit 112 stores information of a hold-toggle pattern. The information of the hold-toggle pattern may be delivered to second storage unit 112 from an on-chip or off-chip storage location, or by a processor or ATE. The hold-toggle pattern determines in which shift clock cycles in a segment of consecutive shift clock cycles scan chains operating in the hold-toggle mode receive bits based on corresponding bits of test pattern 130 when test pattern 130 is being shifted into scan chains 152. The hold-toggle pattern repeats multiple times during the scan shift period. Control signal generator 115 generates control signals based on the operational mode information and the hold-toggle pattern.

Hold-toggle circuit 120 allows, according to the control signals received from controller 110, some scan chains in scan chains 152 to operate in the full-toggle mode and some other scan chains in scan chains 152 to operate in the hold-toggle mode when test pattern 130 is shifted into scan chains 152, which are then sent into DUT 150.

In order to perform scan chain compression, DUT 150 includes a decompressor 151 and a compactor 154. Decompressor 151 can be an XOR decompressor, a mux/demux decompressor, or a linear feedback shift register (LFSR) based decompressor. Decompressor 151 expands compressed input test pattern 130 into internal scan-ins. Compactor 154 can an XOR compactor or a multiple input signature register (MISR) based compactor. Compactor 154 compresses internal scan-outs data into output channels by combining multiple test responses into compressed output vectors to be shifted out from DUT 150. The compressed output vectors are compared to the desired outputs in the memory of chip testing system 100 in order to determine a pass/fail status of DUT 150.

### Expander Graphs

An expander graph is a highly connected sparse graph with strong connectivity properties. Basically, it is a finite, undirected graph that satisfies certain expansion properties, and these properties ensure that even though the graph has relatively few edges, it remains “well-connected.” The number of edges is proportional to the number of vertices (i.e., graph is sparse). Removing a small subset of vertices or edges does not significantly disconnect the graph.

Intuitively, it means that a lot of edges of a relatively sparse graph would have to be deleted to make the graph unconnected. Formally, let V be the set of all vertices of a graph. Let S and T be two non-overlapping set of subsets of vertices of V. Let E(S,T) be the set of edges in the graph where one vertex is in S and the other in T. Each undirected edge is treated as two directed edges so E(S,T) denotes directed edges.

The edge boundary of a subset S of the set of vertices V of the graph is denoted by ∂s=E(S,S′) where S′ is the set of vertices V-S. This is the set of edges from the set S to its complement. The edge expansion ratio of G denoted by h(G) is defined as

$$h ( G ) = min \frac{\vert \partial S \vert}{\vert S \vert} s . t . \vert S \vert < \frac{n}{2}$$

h(G) is said to be a c expander if h(G)>c for all vertex subsets S of G, where |S|<n/2. A higher value indicates a better expander graph, meaning that the graph has a more even distribution of edges and is more expandable.

The eigenvalues of the adjacency representation of graphs are given by their spectral values that are denoted by λ₁>λ₂> . . . > λₙ, where λ₁ is the largest eigenvalue, and λ₂ is the second largest eigenvalue. h(G), as defined above, is also related to the spectral gap of the graph that measures the difference between the largest and the second largest eigenvalues of the graph's adjacency matrix. The relationship is given by the following inequality for a d-regular graph, which is as follows:

$$\frac{d - {λ}_{2}}{2} < h ( G ) < \sqrt{2 d ( d - {λ}_{2} )}$$

The field of error correcting codes is also related to expander graphs. The problem of lossless transmission of data through a noisy medium has been reduced to one of finding an appropriate error correcting code C, with a sufficient hamming distance d, such that upon receipt of an erroneous message the correct code word could be looked up by finding the code word that was closest to the erroneous receipt.

Expander graphs can be utilized to construct efficient error correcting codes. In the literature, such constructions are referred to as low-density parity check (LDPC) codes or Gallagher codes. More formally for a m bit code with n parity bits, an adjacency matrix A of size m×n can be constructed where Aᵢⱼ=1 is 1 if parity bit j depends on input bit i. These are known as array codes.

The adjacency matrix A of size m×n described in the previous paragraph is the exact formulation as that of the combinatorial compactor used in scan compression. Here, m is the number of internal scan channels, and n is the number of external scan outs. Matrix Aᵢⱼ=1 if channel i feeds scan out j. Thus, the problems of (1) finding the best expander in a general bipartite graph, (2) finding an error correcting code with the least Hamming distance between the code words, and (3) finding an optimal scan compaction network in the field of scan compression are basically the same problem.

### X-Tolerance Problem

A linear combinational compactor can be represented as a bipartite graph between a set of internal scan channels m to a set of external scan out pins n. For m scan channels and n external scan out pins, this is a m×n adjacency matrix A, where Aᵢⱼ=1 if channel i drives scan out j. Intuitively, the rows of the matrix are the scan channels, and the columns are the external scan outs. The compaction ratio is m/n. Each channel i fanouts to exactly d scan out pins.

The main problem in scan compression is the presence of Xs at the output of the channels. In the absence of Xs, the matrix A is the parity check matrix of a binary linear code of length m and minimum Hamming distance d.

The following rules are intended for error correcting codes in compactors that have been created using the above-mentioned formulation. In order to allow errors to be observed, the following rules are observed:
(I) No row should be all zeros.
(II) All rows should be non-zero and distinct.
(III) All rows should have an odd number of 1's.
(IV) All rows should have an equal number of 1's.
(V) The weight of a row i is the number of 1s in the i^{th} row of A. To detect an error in the presence of up to k Xs, the weight of a code word should be k+1.
(VI) The compaction ratio is proportional to the number of distinct code words that can be formed.

The girth of a graph G is the length of the shortest cycle in the graph. The larger the girth of the graphical representation of A, the larger the number of errors that can be detected by the compactor.

### Generating Compactors Using Expander Graphs

In accordance with a preferred embodiment of the present invention, expander graphs are utilized to generate a compactor for performing scan chain compressions. Based on the above-mentioned relationship and the other properties to find a practical compactor that can detect errors in the presence of up to d Xs, it is enough to construct expander graphs.

Many methods of explicit constructions of expander graphs are known for non-bipartite graphs. For the scan compression problem, explicit constructions of bipartite expander graphs are required. Randomized construction methods are the most amenable to industry usage where compressors of different combinations of scan channels and external scan outs are desired. Randomized constructions have fast runtime and bounded memory requirements. It is well-known that random bipartite graphs have good expander properties.

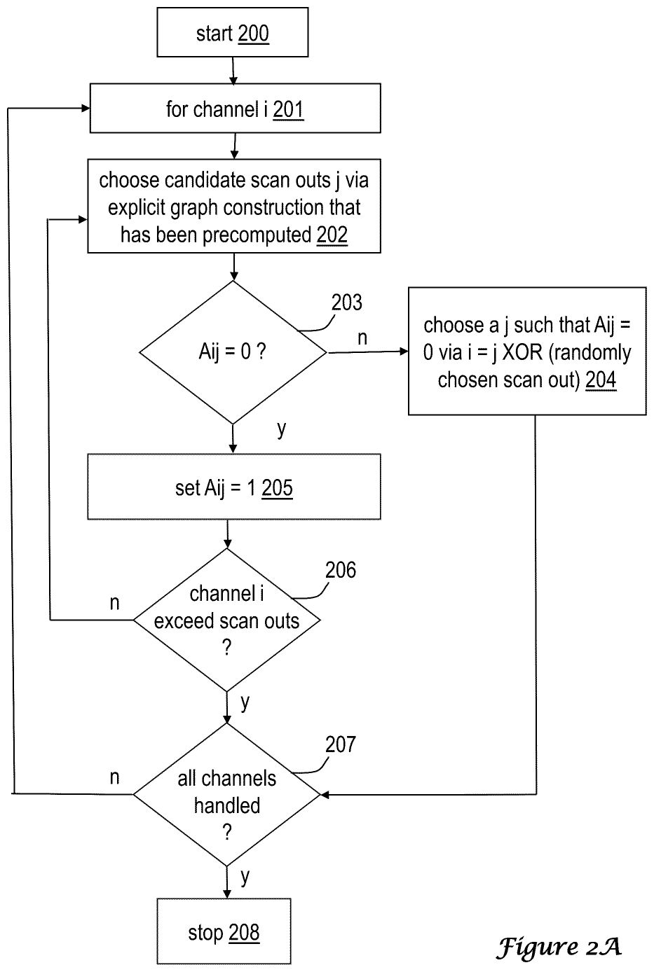

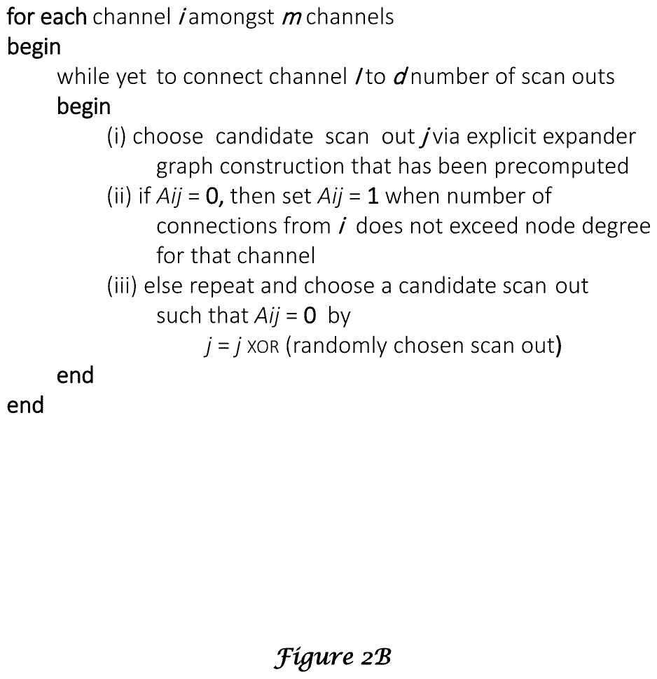

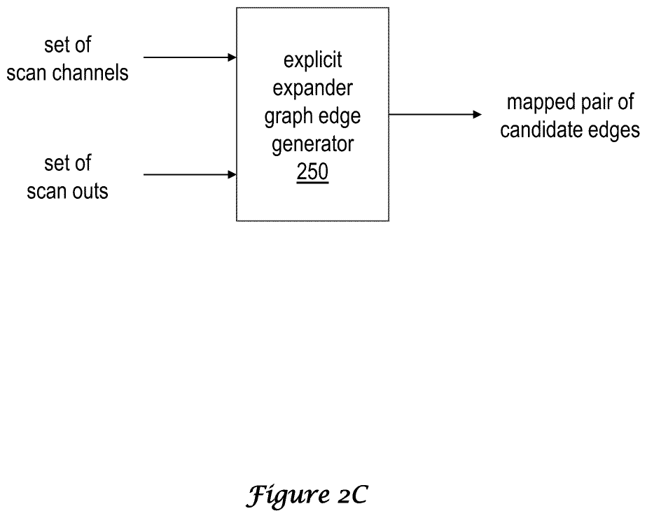

With reference now to FIG. 2A, there is illustrated a flowchart of an algorithm for using expander graphs to generate a compactor to be utilized in scan chain compression for testing IC chips, according to one embodiment of the present invention. Starting at block 200, for each i channel within m channels, at block 201, a candidate scan out j is chosen via explicit expander graph construction that has been precomputed, as depicted in block 202. Next, a determination is made as to whether or not Aᵢⱼ equals zero, as shown in block 203. If Aᵢⱼ does not equal zero, a j is chosen via j=j⊕(randomly chosen scan out) such that Aᵢⱼ=0, as depicted in block 204, and the process continues to block 207. Otherwise if Aᵢⱼ equals zero, set Aᵢⱼ=1, as shown in block 205. Next, a determination is made as to whether or not the channel has exceeded the scan out degree, as depicted in block 206. If the channel has not exceeded the scan out degree, the process returns to block 202. Otherwise if the channel has exceeded the scan out degree, the process continues block 207. Another determination is made as to whether or all the channels have been handled, as shown in block 207. If there are channels needed to be handled, the process returns to block 201. If all the channels have been handed, the process stops, as depicted in block 208.

The compactor generated meets the critical requirement for X-tolerance by virtue of the weight for the row being d (i.e., x+1, where x is the number of Xs being tolerated). All the properties from (I) to (VI) are met by this matrix.

The pseudo code for the flowchart from FIG. 2A is depicted in FIG. 2B.

FIG. 2C illustrates an explicit expander graph edge generator 250 that uses the pseudo code from FIG. 2B to combine a set of scan channels and a set of scan outs to generate a mapped pair of candidate edges.

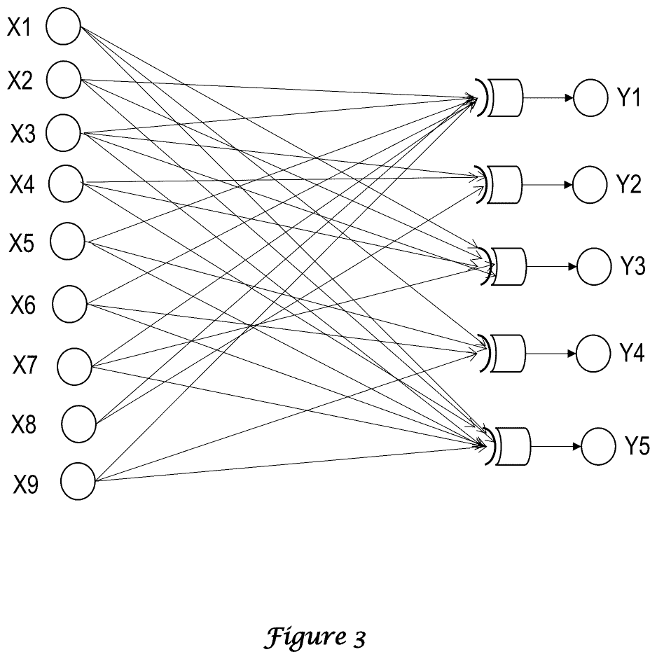

An example of an adjacency matrix of a compactor having 9 scan channels and 5 scan outs is shown in Table I and in FIG. 3.

TABLE I

| | Y1 | Y2 | Y3 | Y4 | Y5 |
|---|---|---|---|---|---|
| X1 | 0 | 0 | 1 | 1 | 1 |
| X2 | 1 | 0 | 1 | 0 | 1 |
| X3 | 1 | 1 | 1 | 0 | 0 |
| X4 | 0 | 1 | 1 | 0 | 1 |
| X5 | 1 | 0 | 0 | 1 | 1 |
| X6 | 1 | 0 | 0 | 1 | 1 |
| X7 | 1 | 0 | 1 | 0 | 1 |
| X8 | 1 | 1 | 0 | 0 | 1 |
| X9 | 1 | 0 | 0 | 1 | 1 |

After the adjacency matrix has been generated, additional refinement is needed to ensure that the binary representation of each row is distinct. In this case, the compression ratio is the number of unique integer value that can be represented by the adjacency matrix in question. In addition, the above-mentioned condition (VI) is also satisfied.

The refinement algorithm can be explained by using the 9 scan channel/5 scan out example shown in Table 1. In Table I, rows 4, 5 and 8 (which corresponds to scan channels X5, X6 and X9 respectively) have the same binary representation of 10011 (i.e., 19). Rows 1 and 6 (which corresponds to scan channels X2 and X7, respectively) have the same binary representation of 10101 (i.e., 21). Table II shows the initial hash table H for the compactor of Table I.

TABLE II

| | |
|---|---|
| 3 | 0 |
| 21 | 1, 6 |
| 28 | 2 |
| 13 | 3 |
| 19 | 4, 5, 8 |
| 25 | 7 |

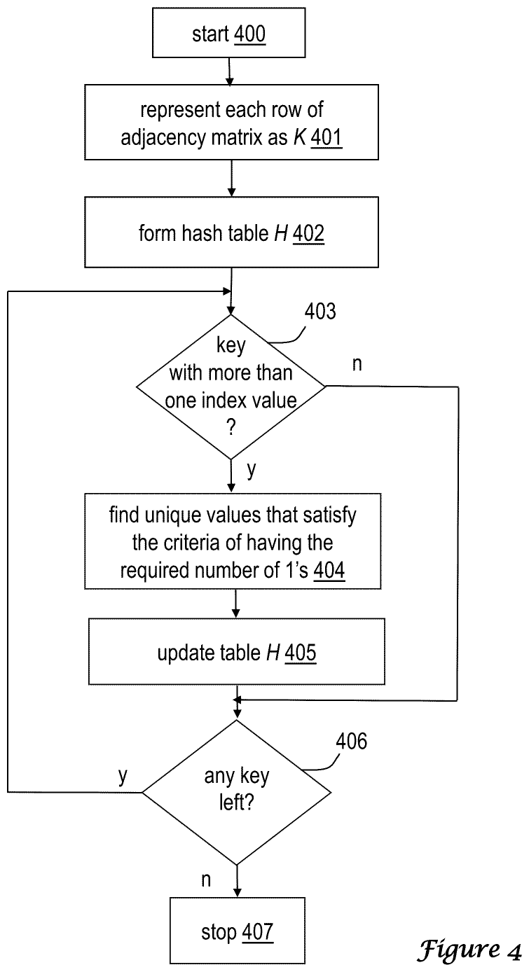

With reference now to FIG. 4, there is illustrated a flowchart of the refinement algorithm, according to one embodiment of the present invention. Starting at block 400, each row of the adjacency matrix is represented as a 64-bit integer key K, as shown in block 401. This is reasonable as the number of scan outs is not expected to be greater than 64. Next, a hash table H is formed, as depicted in block 402, where each entry is a key K as computed above, and the value is the list of indices in the adjacency matrix with the same K value. As an example, for the adjacency matrix shown in Table I, the hash table H should look like the one shown in Table II.

It is required that each key K only has one index value in the table. Also, each key K should have the required number of 1's set in their binary representation to account for the X-tolerance criteria. Thus, a determination is made as to whether or not a key K has more than one index value in the table, as shown in block 403. If a key K has only one index value, the process proceeds to block 406.

If a key K has more than one index value, then a unique binary representation of the key is determined, as depicted in block 404. The unique binary representation of the key is a unique value that satisfies the criteria of having the required number of 1's. The hash table H is updated to reflect that the key only has one index value, as shown block 405. Next, a determination is made as to whether or not there is any remaining key left, as depicted in block 406. If there is still remaining key left, the process returns to block 403; otherwise; the process stops at block 407.

The updated hash table H for the compactor is shown in Table III.

TABLE III

| | |
|---|---|
| 3 | 0 |
| 21 | 1 |
| 28 | 2 |
| 13 | 3 |
| 19 | 4 |
| 25 | 7 |
| 14 | 6 |
| 22 | 5 |
| 26 | 8 |

The core of the work is the generation of the matrix A described above. Each column of the matrix j corresponding to a scan out is fed by the linear combination of the channels for which Aᵢⱼ=1. The sum of fan ins of the scan outs is equal to the sum of fan outs of the scan channels.

### Results

The values of second eigenvalue of adjacency matrix of compactor for various compactor configurations and X-tolerance are shown in Table IV.

TABLE IV

| | | | | | | standard | limit on |
|---|---|---|---|---|---|---|---|
| | | | second | | | deviation | second |
| number | number | number | eigenvalue | fan out | mean fan | of fan in | eigenvalue |
| of scan | of | of Xs | of | of scan | in of scan | of scan | per |
| outs | channels | tolerated | compressor | channel | out | out | formula |
| 32 | 1000 | 4 | 13.34 | 5 | 156.59 | 10.13 | 14.47 |
| 32 | 1000 | 3 | 12.52 | 4 | 132.09 | 8.85 | 13.18 |
| 32 | 1000 | 2 | 11.69 | 3 | 128.81 | 8.43 | 12.72 |
| 16 | 300 | 4 | 9.49 | 5 | 93.68 | 6.99 | 11.63 |
| 16 | 300 | 3 | 8.87 | 4 | 74.69 | 6.05 | 10.32 |
| 16 | 300 | 2 | 8.38 | 3 | 62.06 | 8.81 | 9.23 |
| 8 | 80 | 4 | 4.9 | 5 | 43 | 8.18 | 8.48 |
| 8 | 80 | 3 | 5.04 | 4 | 36.375 | 7.1 | 7.68 |
| 8 | 80 | 2 | 5.2 | 3 | 33.38 | 5.54 | 7.10 |

Table IV shows whether the generated compression macro meets expander constraints. The formula relating the second eigenvalue to the degree of the node of a vertex is

$${λ}_{2} \leq \sqrt{{d}_{channel} - 1} + \sqrt{{d}_{scanout} - 1}$$

As shown, λ₂ is less than the theoretical maximum value. In general, the expansion factor is closer to the theoretical bound for larger networks. This proves that the generated compression network is an expander graph.

Table IV shows that for larger compression ratios the fanin of any of the scan outs is less than 15% of the total number of scan channels as is shown by the first 3 rows of this table.

The low standard deviation in the number of fanins shows that the graph has almost equal logic depth between the last flop of a scan channel and the scan out for all such paths. This enables compression tests to be run at a higher clock frequency and for the compression network to be easier to route.

The generated expander graph should meet the criteria of the above equation. The fourth column of Table IV gives the value of the second largest singular value of the generated adjacency matrix and represents the left-hand side of equation 1. Column 8 of this table gives the right-hand side of equation 1 which is computed from Column 5 and Column 6. Here the table shows that the second eigenvalue λ₂ is less than the theoretical maximum value which proves that the generated expander graph, even after the refinement algorithm of FIGS. 2E and 2F, is an expander graph.

Another quality metric that can be observed is how well does the expander graph based algorithm that is given in FIG. 2B perform in terms of delivering an adjacency matrix with all unique values in the binary representation of the row. For example, in the graph of Table II, 3 scan channels have the same row value. Row 6 shares its binary representation with row 1 and rows 5 and 8 share their binary representation with 4. The lesser the number of such rows the better the performance of the expander graph algorithm and the lesser work that the refinement algorithm does.

Table V shows the results of how many rows are affected for the same configuration of scan outs, scan channels and Xs tolerated. As expected, with the increase in the number of scan outs the number of scan channels that share the same binary representation reduces drastically. For the smaller graphs, the combinatorial search space is smaller, and there are more collisions. This proves that the expander graph based algorithm is successful, in generating X-tolerant compactors and only a minimal amount of finding unique code words is done by the refinement algorithm.

TABLE V

| | | | number of |
|---|---|---|---|
| | | | channels |
| | | | that have |
| number of | number of | number of | common |
| scan outs | channels | Xs tolerated | signature |
| 32 | 1000 | 4 | 2 |
| 32 | 1000 | 3 | 18 |
| 32 | 1000 | 2 | 87 |
| 16 | 300 | 4 | 4 |
| 16 | 300 | 3 | 25 |
| 16 | 300 | 2 | 61 |
| 8 | 80 | 4 | 37 |
| 8 | 80 | 3 | 31 |
| 8 | 80 | 2 | 40 |

As has been described, the present invention provides an improved compactor in scan chain compression for testing IC chips.

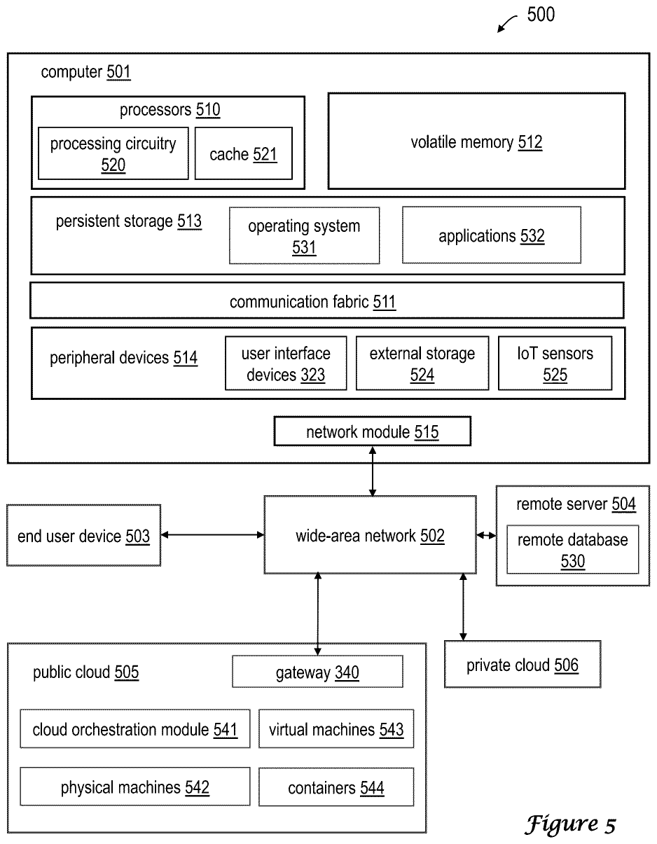

Referring now to FIG. 5, there is illustrated a block diagram of a computing environment in which an embodiment of present invention can be executed. As shown, a computing environment 500 contains an example of an environment for the execution of at least some of the computer code involved in performing the inventive methods, such as a method for testing IC chips via code of one of applications 532. Computing environment 500 also includes, for example, computer 501, wide-area network (WAN) 502, end user device (EUD) 503, remote server 504, public cloud 505, and private cloud 506. In this embodiment, computer 501 includes processor 510 having processing circuitry 520 and cache 521, communication fabric 511, volatile memory 512, persistent storage 513 (including operating system 531 and applications 532), peripheral devices 514 (including user interface devices 523, and Internet of Things (IoT) sensors 525), and network module 515. Public cloud 505 includes a gateway 540, a cloud orchestration module 541, physical machines 542, virtual machines 543, and containers 544.

Computer 501 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database. As is well understood in the art of computer technology, and depending upon the technology, performance of a computer-implemented method may be distributed among multiple computers and/or between multiple locations. On the other hand, in this presentation of computing environment 500, detailed discussion is focused on a single computer, specifically computer 501, to keep the presentation as simple as possible. Computer 501 may be located in a cloud. On the other hand, computer 501 is not required to be in a cloud except to any extent as may be affirmatively indicated.

Processors 510 include one or more processing elements of any type now known or to be developed in the future. Processing circuitry 520 may be distributed over multiple packages, for example, multiple, coordinated integrated circuit chips. Processing circuitry 520 may implement multiple processor threads and/or multiple processor cores. Cache 521 is memory that is located in the processor chip package(s) and is typically used for data or code that should be available for rapid access by the threads or cores running on processors 510. Cache memories are typically organized into multiple levels depending upon relative proximity to the processing circuitry. Alternatively, some, or all, of the cache for the processor set may be located off chip. In some computing environments, processors 510 may be designed for working with qubits and performing quantum computing.

Computer readable program instructions are typically loaded onto computer 501 to cause a series of operational steps to be performed by processors 510 of computer 501 and thereby effect a computer-implemented method, such that the instructions thus executed will instantiate the methods specified in flowcharts and/or narrative descriptions of computer-implemented methods included in this document (collectively referred to as the inventive methods). These computer readable program instructions are stored in various types of computer readable storage media, such as cache 521 and the other storage media discussed below. The program instructions, and associated data, are accessed by processors 510 to control and direct performance of the inventive methods. In computing environment 500, at least some of the instructions for performing the inventive methods may be stored as applications 532 within persistent storage 513.

Communication fabric 511 is the signal conduction paths that allow the various components of computer 501 to communicate with each other. This fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 512 is any type of volatile memory now known or to be developed in the future. Examples include dynamic type random-access memory (RAM) or static type RAM. Volatile memory 512 is characterized by random access, but this is not required unless affirmatively indicated. In computer 501, volatile memory 512 is located in a single package and is internal to computer 501, but, alternatively or additionally, volatile memory 512 may be distributed over multiple packages and/or located externally with respect to computer 501.

Persistent storage 513 is any form of non-volatile storage for computers that is now known or to be developed in the future. The non-volatility of this storage means that the stored data is maintained regardless of whether power is being supplied to computer 501 and/or directly to persistent storage 513. Persistent storage 513 may be a read-only memory (ROM), but typically at least a portion of the persistent storage allows writing of data, deletion of data and re-writing of data. Some familiar forms of persistent storage include magnetic disks and solid state storage devices. Operating system 531 may take several forms, such as various known proprietary operating systems or open source Portable Operating System Interface type operating systems that employ a kernel. The code included in applications 532 includes at least some of the computer code involved in performing the inventive methods.

Peripheral devices 514 include the set of peripheral devices of computer 501. Data communication connections between the peripheral devices and the other components of computer 501 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, user interface (UI) devices 523 may include components such as a display screen, speaker, microphone, wearable devices (such as goggles and smart watches), keyboard, mouse, printer, touchpad, game controllers, and haptic devices. External storage 524 can be an external hard drive, or insertable storage, such as an SD card. External storage 524 may be persistent and/or volatile. In some embodiments, external storage 524 may take the form of a quantum computing storage device for storing data in the form of qubits. In embodiments where computer 501 is required to have a large amount of storage (for example, where computer 501 locally stores and manages a large database), then this storage may be provided by peripheral storage devices designed for storing very large amounts of data, such as a storage area network (SAN) that is shared by multiple, geographically distributed computers. IoT sensors 525 are made up of sensors that can be used in Internet-of-Things applications. For example, one sensor may be a thermometer and another sensor may be a motion detector.

Network module 515 is the collection of computer software, hardware, and firmware that allows computer 501 to communicate with other computers through WAN 502. Network module 515 may include hardware, such as modems or WiFi signal transceivers, software for packetizing and/or de-packetizing data for communication network transmission, and/or web browser software for communicating data over the internet. In some embodiments, network control functions and network forwarding functions of network module 515 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can be downloaded to computer 501 from an external computer or external storage device through a network adapter card or network interface included within network module 515.

WAN 502 is any wide-area network (for example, the internet) capable of communicating computer data over non-local distances by any technology for communicating computer data, now known or to be developed in the future. In some embodiments, WAN 502 may be replaced and/or supplemented by local-area networks (LANs) designed to communicate data between devices located in a local area, such as a WiFi network. The WAN and/or LANs typically include computer hardware such as copper transmission cables, optical transmission fibers, wireless transmission, routers, firewalls, switches, gateway computers and edge servers.

End user device (EUD) 503 is any computer system that is used and controlled by an end user (for example, a customer of an enterprise that operates computer 501), and may take any of the forms discussed above in connection with computer 501. EUD 503 typically receives helpful and useful data from the operations of computer 501. For example, in a hypothetical case where computer 501 is designed to provide a recommendation to an end user, this recommendation would typically be communicated from network module 115 of computer 501 through WAN 502 to EUD 503. In this way, EUD 503 can display, or otherwise present, the recommendation to an end user. In some embodiments, EUD 503 may be a client device, such as thin client, heavy client, mainframe computer, desktop computer and so on.

Remote server 504 is any computer system that serves at least some data and/or functionality to computer 501. Remote server 504 may be controlled and used by the same entity that operates computer 501. Remote server 504 represents the machine(s) that collect and store helpful and useful data for use by other computers, such as computer 501. For example, in a hypothetical case where computer 501 is designed and programmed to provide a recommendation based on historical data, then this historical data may be provided to computer 501 from a remote database of a remote server 504.

Public cloud 505 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 505 is performed by the computer hardware and/or software of cloud orchestration module 541. The computing resources provided by public cloud 505 are typically implemented by virtual computing environments that run on various computers making up the computers of host physical machines 542, which is the universe of physical computers in and/or available to public cloud 505. Virtual computing environments (VCEs) typically take the form of virtual machines from virtual machines 543 and/or containers from containers 544. It is understood that these VCEs may be stored as images and may be transferred among and between the various physical machine hosts, either as images or after instantiation of the VCE. Cloud orchestration module 541 manages the transfer and storage of images, deploys new instantiations of VCEs and manages active instantiations of VCE deployments. Gateway 540 is a collection of computer software, hardware, and firmware that allows public cloud 505 to communicate through WAN 502.

Private cloud 506 is similar to public cloud 505, except that the computing resources are only available for use by a single enterprise. While private cloud 506 is depicted as being in communication with WAN 502, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 505 and private cloud 506 are both part of a larger hybrid cloud.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, RAM, ROM, erasable programmable read-only memory (EPROM), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

While the invention has been particularly shown and described with reference to a preferred embodiment, it will be understood by those skilled in the art that various changes in form and detail may be made therein without departing from the spirit and scope of the invention.

What is claimed is:

1. A method comprising:
generating a compactor by using explicit expander graphs;
inserting said generated compactor and a decompressor within a device-under-test (DUT),
feeding a compressed test pattern into said DUT;
expanding said compressed test pattern via said decompressor into internal scan-ins within said DUT;
compressing internal scan-outs data into compressed output vectors via said generated compactor;
shifting out said compressed output vectors from said DUT; and
comparing said compressed output vectors to a set of desired outputs in order to determine a pass/fail status of said DUT.

2. The method of claim 1, wherein said generating further includes combining a set of internal scan channels and a set of external scan outs to generate a set of mapped pair of candidate edges.

3. The method of claim 1, wherein said generating further includes representing said compactor as a bipartite graph between a set of internal scan channels m to a set of external scan out pins n in said expander graph.

4. The method of claim 1, wherein said generating further includes verifying that no two rows in a hash table have the same binary representation.

5. The method of claim 4, wherein said generating further includes verifying that said generated compactor meets expander graph criteria.

6. A computer program product for performing integrated circuit testing, said computer program product comprising a computer readable storage medium having program instructions embodied therein, said program instructions executable by a computer to cause said computer to perform:
generating a compactor by using explicit expander graphs;
inserting said generated compactor and a decompressor within a device-under-test (DUT),
feeding a compressed test pattern into said DUT;
expanding said compressed test pattern via said decompressor into internal scan-ins within said DUT;
compressing internal scan-outs data into compressed output vectors via said generated compactor;
shifting out said compressed output vectors from said DUT; and
comparing said compressed output vectors to a set of desired outputs in order to determine a pass/fail status of said DUT.

7. The computer program product of claim 6, wherein said generating further includes combining a set of internal scan channels and a set of external scan outs to generate a set of mapped pair of candidate edges.

8. The computer program product of claim 6, wherein said generating further includes representing said compactor as a bipartite graph between a set of internal scan channels m to a set of external scan out pins n in said expander graph.

9. The computer program product of claim 6, wherein said generating further includes verifying that no two rows in a hash table have the same binary representation.

10. The computer program product of claim 9, wherein said generating further includes verifying that said generated compactor meets expander graph criteria.

11. A data processing system for testing integrated circuits, said data processing system comprising:
processing circuitry; and
a storage device coupled to said processor circuitry, wherein said storage device includes program code executable by said processing circuitry to cause said data processing system to perform:
generating a compactor via explicit expander graphs;
inserting said generated compactor and a decompressor within a device-under-test (DUT),
feeding a compressed test pattern into said DUT;
expanding said compressed test pattern via said decompressor into internal scan-ins within said DUT;
compressing internal scan-outs data into compressed output vectors via said generated compactor;
shifting out said compressed output vectors from said DUT; and
comparing said compressed output vectors to a set of desired outputs in order to determine a pass/fail status of said DUT.

12. The data processing system of claim 11, wherein said generating further includes combining a set of internal scan channels and a set of external scan outs to generate a set of mapped pair of candidate edges.

13. The data processing system of claim 11, wherein said generating further includes representing said compactor as a bipartite graph between a set of internal scan channels m to a set of external scan out pins n in said expander graph.

14. The data processing system of claim 11, wherein said generating further includes verifying that no two rows in a hash table have the same binary representation.

15. The data processing system of claim 14, wherein said generating further includes verifying that said generated compactor meets expander graph criteria.
